(19) United States
(12) Patent Application Publication
(10) Pub. No.: US 2004/0055631 A1
(43) Pub. Date: Mar. 25, 2004

(54) Hybrid solar energy collector

(76) Inventors: Kazimierz Szymocha, Edmonton (CA); Douglas Willard Lindstrom, Edmonton (CA); Kristian Peter Olsen, Edmonton (CA)

Correspondence Address: DAVIS & BUJOLD, P.L.L.C., FOURTH FLOOR, 500 N. COMMERCIAL STREET, MANCHESTER, NH, 03101-1151, US

(21) Appl. No.: 10/446,618

(22) Filed: May 28, 2003

(30) Foreign Application Priority Data
May 28, 2002 (CA) 2,338,195

(51) Int. Cl. H02N 6/00; H01L 25/00; H01L 31/00

(52) U.S. Cl. 136/243

(57) ABSTRACT

A hybrid solar energy collector has a photovoltaic collector that generates electricity and a thermal collector that generates heat. The photovoltaic collector, which is semi-transparent, utilizes shorter-wavelength radiation while selectively transmitting medium- and long-wavelength radiation to the thermal collector. The collectors are separated by a thermal insulating barrier.

### FIELD OF THE INVENTION

The present invention relates to a hybrid solar energy collector system which extracts useable energy from solar radiation by means of a photovoltaic collector in combination with a thermal collector.

### BACKGROUND OF THE INVENTION

Combined photovoltaic/thermal solar energy collectors have been the subject of interest for the last few years and are regarded as a one of the most promising solutions for the reduction of greenhouse gases emissions. A growing number of applications for solar energy collection systems are driving the quest for more efficient and less expensive systems. The hybrid solar collecting system is expected to collect most if not all of the available solar energy that is delivered by solar radiation to the sun exposed surface. The main reasons for a hybrid solar energy system are a combination of improvement of system efficiency and reduction of panel manufacturing and installation costs. The potential for electrical energy generation by existing photovoltaic (PV) collectors is about 12 to 15%. The rest of the incident solar energy is transformed into heat that has to be dissipated to the environment (waste heat), otherwise it will cause collector overheating and efficiency reduction. The potential of heat production by thermal solar collectors is much higher, as the efficiency can be in the range from 50% to 80%. A promising way to improve the overall collecting system efficiency is to integrate these two collectors together. With the current technologies, the PV/thermal collector combination is a subject of significant interest as the hybrid solar collectors occupy less space than two separate collectors, and need less materials. Installation costs and the total energy and economy balance may also be better than for two separate units.

The PV/thermal combined collectors are called hybrid solar collectors. By their application the useable energy yield per area unit of the collecting system can be substantially increased, and solar energy systems can be made more cost effective. The sunlight spectrum is generally distributed over a wavelength range of about 0.3 μm to 2.5 μm with a peak near the wavelength of 0.5 μm. It is known that PV collectors absorb a considerable fraction of the light with wavelengths of less than about 0.8 μm, while scarcely absorbing light with wavelengths longer than 0.8 μm. This means that the rest of the solar radiation spectrum is not utilized contributing to undesirable effects such as PV cell heating and thermal degradation, and in consequence, reduction of cell efficiency and life expectancy. The current development of solar energy collecting hybrid systems is based on recovery and utilization of thermal energy dissipated from within existing PV collectors by forcing a flow of a cooling medium for heat removal from PV panels. Hybrid solar collectors can be used in most solar systems installed on residential houses and buildings as well as for industrial purposes. Two different photovoltaic/thermal (PV/T) collectors (liquid cooled or air cooled) are currently available. The operating temperature has significant impact on PV cell performance. Typically the power decreases about 2-5% per each 10° C. temperature increase. It is obvious that removal of the excessive heat from the module, hereby potentially increasing the electrical yield and providing solar thermal energy for the house, is a good solution.

TABLE 1
Combined PV/T Modules Manufacturers

| | | |
|---|---|---|
| Conserval Engi- | Canada | www.solarwall.comm.html#12c |
| neering Inc. | | |
| Grammer KG | Germany | www.solarwerk.de/spectrum.htm |
| Phototronies Solar- | Germany | www.ase- |
| technik (part | | interntional.com/english/start_e.html |
| of ASE) | | |
| ICEC AG | Switzerland | www.icec.ch/products.html |
| Sekisui Chemical | Japan | www.sekisui.co.jp |
| Co., Ltd | | |

The commercially available PV/thermal collectors are mostly PV cells directly integrated with the thermal absorbers were the both PV and thermal absorber operate essentially at the same temperature. To a certain extent existing hybrid collectors, that operate at a single temperature, can be regarded as a PV modules with a cooling system. The PV collectors are installed on plate that has attached channels for heat removal by flow of fluid and is regarded as a heat absorber. Herein lies a problem: An operating temperature of, say 30° C. is too low for efficient use of a hot water heating system, whereas operation at 60° C. is too high for efficient photovoltaic collector operation. In fact, the efficiency of a photovoltaic collector drops sharply with increasing operating temperature. Extensive testing of the existing hybrid modules identified also a problem with maintaining the long-term stability of the PV cells when operating at temperatures required for hot water systems. The operating temperature for existing domestic hot water system is typically set at 55° C. However, in the existing solutions a tradeoff is made between efficiency of conversion to either electrical power or useful thermal power with an operating temperature compromise.

Ideally, a hybrid collector should minimize the thermal heat generation within the photovoltaic collector and maximize it in the thermal collector.

Interesting examples of the existing solutions are discussed in following patents: The Geritt de Wilde U.S. Pat. No. 4,080,954 describes an all-glass vacuum tube thermal collector with a semicircular concave cylindrical reflector deposited on its inner surface. In the focal plane of the reflector is heat absorption tubing made from blackened glass. Inside is a circulating heat transfer fluid. A patent by Faramarz Mahdjuri DE 2,612,171 (or U.S. Pat. No. 4,159,706) describes a similar solution that uses a reflective metallic layer. Both approaches have disadvantages: They only generate thermal energy, are fragile and sensitive to shocks, and the tubes are difficult to manufacture. Shimada et al, (U.S. Pat. No. 4,409,964) and Tonomura et al. (U.S. Pat. No. 4,413,616) describe similar devices. A patent by Gregory W.

Knowles et al (U.S. Pat. No. 4,119,085) discloses a heat pipe device. In this application the heat pipe is another type of vacuum tube. The-collector is equipped with a solar radiation concentration system. A combined collector-reflector system is supposed to increase the amount of solar energy directed to the collector. Sabet (U.S. Pat. No. 4,311,131), Mahdjuri (U.S. Pat. No. 4,313,423) and Mahdjuri and Sabet (U.S. Pat. No. 4,523,578) give additional descriptions of heat pipe thermal collectors. Descriptions of hybrid photovoltaic-thermal solar modules solutions are given by DeVries et al., (Patent WO 99/10934), Hwa Rang Patent (WO 99/30089), Oster (U.S. Pat. No. 4,238,247), and Kosaka et al. (U.S. Pat. No. 4,587,376).

The DeVeries (Pat. WO 99/10934) device places a photovoltaic module directly on a metal plate. The metal plate serves as a thermal collector. In this embodiment of the invention, flow channels are provided by pipes or tubes, which are in thermal contact with the metal plate and used to absorb heat. Similar devices found in the patent literature also place the PV module in direct contact with a thermal collector (see below). Direct contact between PV and thermal collectors mean that they must operate at the same temperature. The drawback is that the high temperature required for an efficient thermal collector will be too high for efficient operation of the PV collector. Conversely, a low temperature for an efficient PV collector will be too low for efficient thermal collection. Soule (U.S. Pat. No. 4,700,013) applies a solar radiation concentrator that is separated from other collecting systems, but the design is overly complex. The basic problem of the DeVeries device is the temperature of the PV module. It operates at 60° C., which gives good thermal collection efficiency but poorer performance of the silicon PV collector. U.S. Pat. No. 4,587,376 presents a hybrid system that is particularly suited for an amorphous silicon PV collector.

### SUMMARY OF THE INVENTION

What is required is a hybrid solar energy collecting system which makes more effective utilization of the total solar spectrum.

This invention relates to a hybrid solar energy collecting system for effective utilization of the total solar spectrum. The system includes two solar radiation collectors that are thermally isolated from each other. The collectors operate by utilizing different fractions of the entire solar radiation spectrum, and first generates electricity and second thermal energy (i.e. high-temperature). The solar radiation fraction used by each collector is designed in a way to minimize internal heating the PV collector and maximize the operating temperature in the thermal collector. Therefore, the device also enhances efficiency keeping the PV collector temperature low and the thermal collector temperature high. A low PV collector operating temperature also enhances its operational life preventing its thermal degradation. Selective transmission of longer-wavelength radiation through the photovoltaic collector minimizes its own heat generation and maximizes the heating potential of the thermal collector. Thermal isolation of the collectors means that the hybrid system solution is suited for optimal performance.

In summary, the inventors present a unique hybrid system. It employs a selectively transparent PV collector that transmits portion of radiant solar energy to a thermally separated heat collector. This thermal collector operates at a higher temperature than the PV collector.

The said hybrid collector may be used to efficiently convert the entire solar spectrum into useful energy. The approach is regarded as an inexpensive solar collector, which produces electric energy from shorter- to medium-wavelength radiation and high-temperature thermal energy from medium- to long-wavelength radiation. This hybrid solar system require significantly less space than a combination of stand-alone electric and thermal solar collectors.

### BRIEF DESCRIPTION OF THE DRAWINGS

The invention will further be described by way of example, with reference to the accompanying drawings, in which:

FIG. 1 is a cross-sectional end view of a preferred embodiment of the hybrid solar panel based on the vacuum tube type solar collector with transparent PV layers deposited on glass enclosure.

FIG. 2 is a side elevation view, in section, of another embodiment of the hybrid solar panel based on transparent PV panel combined with flat thermal solar panel.

FIG. 3., labelled as PRIOR ART, is a perspective view of a typical solar vacuum tube collector

FIG. 4, labelled as PRIOR ART, is a perspective view of a heat pipe vacuum tube collector

### DETAILED DESCRIPTION OF THE INVENTION

This invention provides a solution for a hybrid photovoltaic-thermal solar module that is simple to manufacture, reduces costs and the amount of material used, optimizes operation conditions and improves electrical and thermal efficiency. In typical PV cells a portion of medium- to longer-wavelength radiation is adsorbed by the PV module. This causes heat generation and therefore higher PV operating temperature. High operating temperature result in decreased efficiency and reduced life expectancy.

According to this invention, the hybrid solar energy collector consists of two thermally isolated collectors. The first is for generation of electricity, with an efficiency of about 14%. The second is for heat or hot water generation with efficiency of about 70%. As a result, the total collected solar energy efficiency can be as high as 85%. This is an improvement over systems that collect only heat or electrical power, and to get the same energy by traditional methods would require almost twice as much of collecting (roof) space.

More specifically, the invention relates to a vacuum tube type collector, with a thermal collector inside and a selectively transparent photovoltaic collector on the outside, or a flat panel thermal collector covered by a thermally isolated, selectively transparent photovoltaic collector. In either case, it is subject of this patent solution that the photovoltaic panel operates at significantly lower temperature than the thermal collector.

The thermal collector can be regarded as a heat sink for the photovoltaic module, in the sense that it preferentially absorbs the portion of radiation that has low electrical conversion efficiency and in standard solution unnecessary heats the PV panel causing reduction of efficiency.

A two-layer hybrid solar collector is made by forming a PV collector that is selectively transparent and placed over top of a thermal collector. The wavelength selectivity causes absorption and conversion of short- to medium-wavelength sunlight (e.g. <0.8 μm) into electricity. At the same time, medium- to longer-wavelength sunlight (e.g. >0.8 μm) is not absorbed. Instead, this light is transmitted through the PV and strikes a thermal collector.

The thermal collector could be within a vacuum tube or simply in the form of a flat panel, separated from the PV collector by an air gap.

In a first embodiment of the invention, a thermal collector is placed inside a vacuum tube. A photovoltaic collector that is transparent to medium- and long-wavelength radiation is placed on the exterior surface of said vacuum tube, and the vacuum itself serves as the thermal insulating barrier. In this embodiment of the invention, high system efficiency is achieved when the transparent PV collector is deposited directly on flattened vacuum tubes, inside which are thermal collectors.

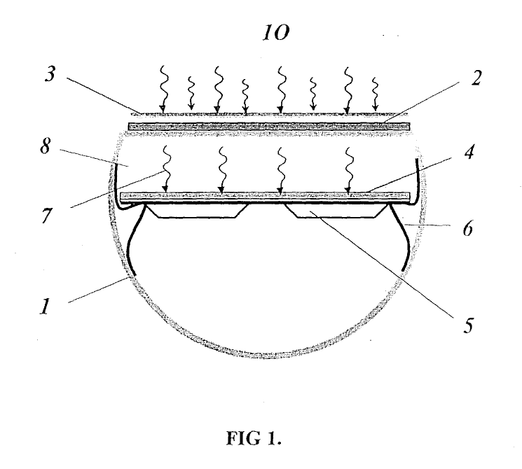

FIG. 1 shows view/cross section of hybrid modules applying thermal vacuum module with modified shape of tube. Thin, selectively transparent layers of a PV are deposited on one side of glass tube. In this case the costs of PV system are significantly less than a typical PV collector. The additional weight resulted from deposition of the PV layers also becomes negligible. There is therefore no need for a thick, protective/supportive layers of glass as applied in a standard PV panel. The hybrid module comprises a glass tube 1 with thermal collecting plate 4, with a heat transfer channels 5 and a photovoltaic laminate consisting of photovoltaic cells 2 of thin (e.g. crystalline silicon) material, which is mounted on the glass tube surface and covered with a protective layer 3. Total solar radiation 10 is partially absorbed in the transparent PV cell 2 and the transmitted portion of solar radiation 7 is transferred to the thermal collector 4. Thermal collector plate 4 is secured by supporting elements 6.

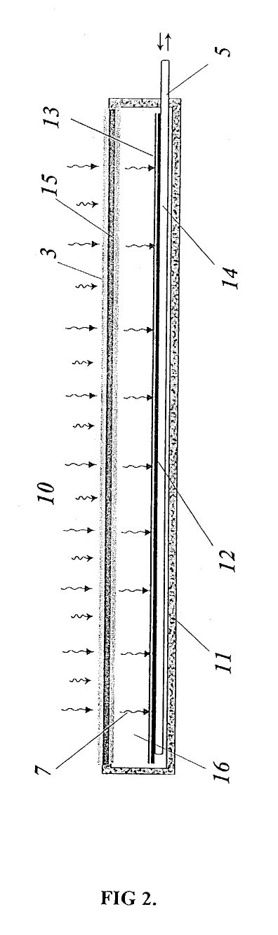

An alternative solution consists of said photovoltaic collector installed in front of a flat thermal collector with an air gap acting as the thermal insulating barrier. Both collectors are positioned sufficiently far away one from other to reduce the heat exchange between the PV collector and the thermal collector. In accordance with the invention, the simplest design is where the selectively transparent PV collector is mounted on top of a flat thermal solar collector. Normally a glass plate mechanically protects the thermal collector and gives thermal isolation from the normally cooler air, but in this case the PV collector serves both purposes. In a second embodiment as shown in FIG. 2 a solution of hybrid system with the structure that is similar to typical flat thermal panel is presented. It is an enclosure 11covered by a selectively transparent PV module 15 that is implemented instead of protective glass. On top of the semitransparent PV module 15 a protective and antireflective coating 3 is deposited. The thermal collector plate 12 (e.g. a metal), that is separated from the transparent PV module 15 with thermally protective air gap 16, is coated with an another layer that readily absorbs the infrared spectrum of solar radiation and is equipped with a heat removal pipe 14. The said heat removal pipe contains a heat transfer fluid such as glycol or water.

In the presented designs, the thermal collector absorbs less sunlight through a PV collector, but in every other sense acts as a stand-alone system. In both embodiments a significant material and cost savings can be achieved and the total solar energy gain form the solar exposed surface is maximized. This allows the present invention to offer a hybrid collector in which all the wavelengths of sunlight may be effectively utilized for the cogeneration of electrical power and useful heat. Three aspects of the hybrid collector are key. First, the use of semi-transparent PV collector that is located on top of thermal collector and splits a solar radiation into two streams—absorbed and transmitted. Second, the portion of solar radiation that passes through the PV collector is adsorbed in the thermal absorber collector to generate heat. Third, the thermally insulating barrier between collectors restricts conductive heat transfer from the thermal collector back to the photovoltaic collector. This allows the PV collector to operate at low temperature and the thermal collector to operate at a high temperature.

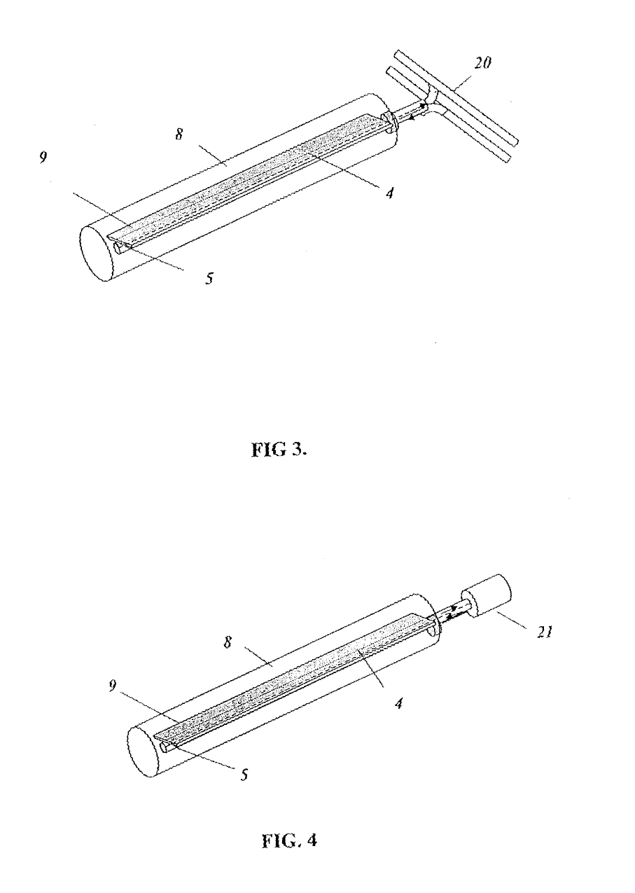

FIG. 3 presents the existing solutions for the vacuum tube collectors with manifold 20

FIG. 4 present the existing solutions for the heat pipe vacuum tube collector with condenser 21.

What is claimed is:

1. A hybrid solar energy collector comprising:
a transparent body having an interior cavity and an exterior surface;
a thermal energy collector disposed within the interior cavity of the body;
one of a transparent or semi-transparent photovoltaic energy collector positioned on the exterior surface of the body, the photovoltaic energy collector being thermally insulated from heat generated by the thermal energy collector.

2. The hybrid solar energy collector as defined in claim 1, wherein the body is an elongate tube.

3. The hybrid solar energy collector as defined in claim 1, wherein the photovoltaic energy collector is thermally insulated from the thermal energy collector by a vacuum.

4. The hybrid solar energy collector as defined in claim 1, wherein the photo-voltaic energy collector is thermally insulated from the thermal energy collector by an air gap.

5. The hybrid solar energy collector as defined in claim 1, wherein the thermal energy collector includes a heat exchange conduit through which fluid is circulated to recover heat from the thermal energy collector.

6. A hybrid solar energy collector comprising:
a thermal energy collector having an transparent exterior glass surface and a solar radiation collecting plate adapted to absorb solar radiation and generate heat; a semi-transparent photovoltaic energy collector positioned on the exterior glass of the thermal collector, the collecting plate being spaced from the photovoltaic energy collector with a thermally insulating air gap preventing heat exchange between the collecting plate and the photovoltaic energy collector; and
heat exchange conduits with circulating fluid attached to the collecting plate to recover heat from the thermal energy collector.

7. A hybrid solar energy collector comprising:
a thermal energy collector having an transparent exterior glass surface and a solar radiation collecting plate adapted to absorb solar radiation and generate heat;
a semi-transparent photovoltaic energy collector positioned on the exterior glass of the thermal collector, the collecting plate being spaced from the photovoltaic energy collector with a thermally insulating a vacuum preventing heat exchange between the collecting plate and the photovoltaic energy collector; and
heat exchange conduits with circulating fluid attached to the collecting plate to recover heat from the thermal energy collector.
